(19) United States
(12) Patent Application Publication
(10) Pub. No.: US 2007/0298553 A1
(43) Pub. Date: Dec. 27, 2007

(54) Thin Film Transistor and Method For Production Thereof

(76) Inventor: Masafumi Kunii, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/763,744

(22) Filed: Jun. 15, 2007

Related U.S. Application Data
(62) Division of application No. 10/942,066, filed on Sep. 15, 2004, now abandoned.

(30) Foreign Application Priority Data
Sep. 29, 2003 (JP) P2003-336939

(51) Int. Cl. H01L 29/04; H01L 31/036; H01L 31/20

(52) U.S. Cl. 438/159; 257/E21.413

(57) ABSTRACT

The production method of the thin film transistor according to the present invention involves the reactive heat CVD process to form the active layer and the source-drain layer. This offers the advantage of eliminating additional steps to crystallize the semiconductor thin film. The resulting stacked thin film transistor is composed of originally crystalline semiconductor thin films. Having the active layer and the source-drain layer formed from crystalline semiconductor thin film, the stacked thin film transistor has a faster working speed than the one formed from amorphous semiconductor thin film. Another advantage of eliminating steps for crystallization is uniform quality which would otherwise be adversely affected by crystallization. In addition, the fact that the source-drain layer is formed from a previously doped crystalline semiconductor thin film means that there is no need for any step to introduce impurities after film formation.

### BACKGROUND OF THE INVENTION

The present invention relates to a thin film transistor and a method for production thereof. The thin film transistor is of the stacked type which is made of polycrystalline silicon. It finds use as an element to drive the liquid crystal display or organic electroluminescence (EL for short hereinafter) of active matrix type.

A display device of active matrix type is provided with thin film transistors (TFT) as driver elements. TFT's are classed into that of stacked type and that of planar structure. The former has an active layer separate from the source-drain region, and the latter has a channel section of the same semiconductor layer as the source-drain region. The TFT of stacked type offers the advantage of requiring less masks in its manufacturing process, which is mentioned in the following.

FIG. 9 is a sectional view showing a stacked TFT of bottom gate type. This TFT is produced as follows. The process starts with sequentially forming on a substrate 101 a gate electrode 102 by pattering, a gate insulating film 103, and a semiconductor film 104 of amorphous silicon not containing impurities by CVD process. The semiconductor film 104 is polycrystallized by irradiation with laser beams and then patterned to be made into an active layer 104a. The active layer 104a of polycrystalline silicon has its central part covered with an insulating protective pattern 105. Then, a semiconductor thin film 106 of amorphous silicon containing impurities is formed by plasma CVD process along with impurity doping. The semiconductor film 106 has its top covered with a metal film 107. The metal film 107 and the semiconductor thin film 106 undergo patterning, thereby forming a source region 106a and a drain region 106b, both made of the semiconductor thin film 106, and electrodes 107a and 107b, both made of the metal film 107. Thus, the stacked TFT of bottom gate type as desired is obtained.

The stacked TFT of bottom gate type produced as mentioned above has the channel formed at the interface between the gate insulating film 103 and the active layer 104a. In addition, this active layer 104a may function as the electric field relaxation region if its impurity concentration is kept below 1017/cm³. (For more detail about the foregoing, refer to the Patent Document 1.)

Japanese Patent Laid-Open No. 2001-102584 (FIG. 1 and paragraphs 0009-0013, in particular)

FIG. 10 is a sectional view showing a stacked TFT of top gate type. This TFT is produced as follows. The process starts with forming a polycrystalline silicon film 202 on a substrate 201. The polycrystalline silicon film 202 is given impurities for the source and drain by ion implantation through a patterned resist mask. The doped polycrystalline silicon film 202 undergoes patterning, so that the source region 202a and the drain region 202b are formed. Then an amorphous silicon film 203 is formed in such a way that it covers the source region 202a and the drain region 202b. The amorphous silicon film 203 is crystallized by irradiation with laser beams and then patterned to give the active layer 203a of polycrystalline silicon. A gate insulating film 204 (shown only in a sectional view) is formed on the active layer 203a. On the active layer 203a is further formed by patterning a gate electrode 205, with the gate insulating film 204 interposed between them. Thus, the stacked TFT of top gate type as desired is obtained. Incidentally, the gate electrode 205 is formed such that it partly overlaps the source region 202a and the drain region 202b. The amount of overlapping is indicated by d1 and d2. The thus specified overlapping sections prevent the parasitic capacity from increasing excessively between the gate electrode 205 and the source region 202a and between the gate electrode 205 and the drain region 202. (For more detail about the foregoing, refer to the Patent Document 2.)

[Patent Document 2]

Japanese Patent No. 275919

Among flat panel displays with TFT driver elements, the organic EL display is composed of selfluminous elements (or organic EL elements). The organic EL element has many important features, such as good color reproducibility, wide viewing angle, high-speed response, and high contrast. The organic EL elements used for the organic EL display are of the current drive type. Therefore, they should preferably be driven by pixel transistors such as polycrystalline silicon TFT's using polycrystalline silicon which are superior in current driving capability. For this reason, the above-mentioned stacked TFT has the active layer and the source/drain formed from polycrystalline silicon, so that it exhibits the high current driving capability.

The conventional process for producing TFT's of polycrystalline silicon is characterized in that the amorphous silicon film is irradiated with excimer laser for conversion into polycrystalline silicon film by melting and recrystallization. However, it suffers the disadvantage of requiring an additional step for recrystallization and resulting in TFT's varying in properties due to fluctuating laser energy.

Moreover, the conventional process employs an ion doping apparatus or an ion implantation apparatus to form the source and drain. Ion doping or ion implantation is followed by thermal annealing or lamp annealing to activate impurities. Unfortunately, these apparatus are applicable only to substrates no larger than approximately 730 by 920 mm² (or substrates of the fourth generation). This is a primary factor that makes it difficult to realize large-sized displays.

### SUMMARY OF THE INVENTION

It is an object of the present invention to provide a thin film transistor and a method for production thereof. The thin film transistor works at a higher speed owing to polycrystalline semiconductor film, permits its driving current to be increased, and exhibits uniform characteristic properties. The manufacturing method is practicable with a less number of steps and is applicable to larger substrates than before.

According to an aspect of the present invention, there is provided a method for producing a thin film transistor including:

a step of forming on a substrate a source-drain layer of polycrystalline semiconductor thin film containing impurities by the reactive heat CVD process that employs the reaction energy of different two or more gases;

a step of forming a source region and a drain region by patterning the source-drain layer;

a step of forming an active layer of polycrystalline semiconductor thin film by the reactive heat CVD process that employs the reaction energy of different two or more gases in such a way that the active layer covers the source region and the drain region;

a step of forming a gate insulating film on top of the active layer; and

a step of forming a gate electrode, with the gate insulating film and active layer interposed under the gate electrode, in such a way that both ends of the gate electrode overlap the edges of the source region and drain region in a specific manner.

According to another aspect of the present invention, there is provided a method for producing a thin film transistor which including:

a step of forming a gate electrode on a substrate and then covering the gate electrode with a gate insulating film;

a step of forming on the gate insulating film an active layer of polycrystalline semiconductor thin film by the reactive heat CVD process that employs the reaction energy of different two or more gases;

a step of forming a source-drain layer of polycrystalline semiconductor thin film containing impurities by the reactive heat CVD process that employs the reaction energy of different two or more gases; and

a step of forming a source region and a drain region by patterning the source-drain layer in such a way that both ends of the gate electrode overlap the edges of the source region and drain region in a specific manner, with the gate insulating film and active layer interposed under the gate electrode.

According to still another aspect of the present invention, there is provided a thin film transistor including a gate electrode, a gate insulating film, an active layer of semiconductor thin film, and source and drain regions formed sequentially, in ascending or descending order mentioned, on a substrate, wherein

The active layer and the source and drain regions are composed of polycrystalline semiconductor thin film formed by the reactive heat CVD process which uses the reaction energy of different two or more gases, and

one edge of the source region and one edge of the drain region overlap both edges of the gate electrode, with the gate insulating film and the active layer interposed under the gate electrode in a specific manner.

As mentioned above, the present invention provides a method for producing a thin film transistor. This manufacturing method is characterized in forming the active layer and the source-drain layer by the reactive heat CVD process. Therefore, it eliminates the steps for crystallizing the semiconductor thin film and introducing impurities into the source-drain layer, and it gives rise to a polycrystalline semiconductor thin film which works at a higher speed. The stacked thin film transistor obtained in this manner permits the driving current, or ON current, to be increased. With this manufacturing method, it is possible to simplify production process, reduce production cost, and eliminate quality variation due to crystallization. Without steps for crystallization and doping, it is possible to form uniform thin film transistors on a larger substrate. This, in turn, helps realize a large-sized display unit with thin film transistors.

The stacked thin film transistor obtained by the above-mentioned manufacturing method is characterized in that the active layer and the source-drain layer are formed from a polycrystalline semiconductor thin film deposited by the reactive heat CVD process. Therefore, it works at a higher speed. Moreover, the source and drain regions are formed such that they overlap the gate electrode in a specific manner. This helps increase the driving current.

The above and other objects, features and advantages of the present invention will become apparent from the following description and the appended claims, taken in conjunction with the accompanying drawings in which like parts or elements denoted by like reference symbols.

### BRIEF DESCRIPTION OF THE DRAWINGS

FIG. 1 is a schematic diagram showing the film forming apparatus which is used for the embodiment.

FIGS. 2A to 2D are sectional views (part 1) showing the manufacturing process which is used for the first embodiment.

FIG. 3 is a plan view showing how the source and drain regions overlap the gate electrode in the first embodiment.

FIGS. 4A and 4B are sectional views (part 2) showing the manufacturing process which is used for the first embodiment.

FIGS. 5A to 5D are sectional views (part 1) showing the manufacturing process which is used for the second embodiment.

FIGS. 6A to 6D are sectional views (part 2) showing the manufacturing process which is used for the second embodiment.

FIG. 7 is a plan view showing how the source and drain regions overlap the gate electrode in the second embodiment.

FIG. 8 is a diagram showing another structure of the stacked TFT of bottom gate type according to the second embodiment.

FIG. 9 is a diagram showing the production of a conventional stacked TFT of bottom gate type.

FIG. 10 is a diagram showing the production of a conventional stacked TFT of top gate type.

### DETAILED DESCRIPTION OF THE PREFERRED EMBODIMENTS

The embodiment of the present invention will be described below with reference to the accompanying drawings. The following description is divided into three sections—the manufacturing apparatus and process and the resulting thin film transistor.

Manufacturing Apparatus

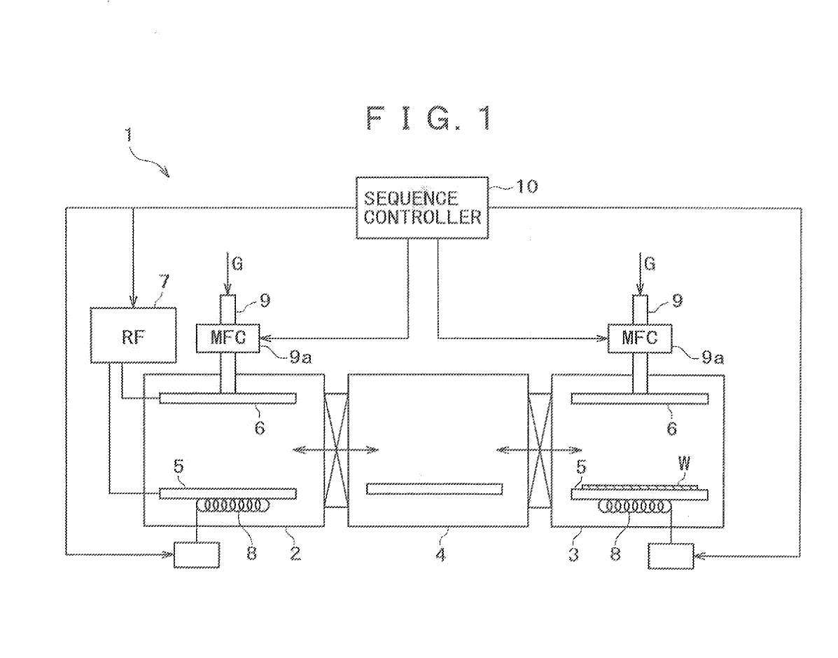

FIG. 1 is a schematic diagram showing an example of the apparatus used in the following embodiment. The apparatus 1 is intended for film deposition. It has two airtight deposition chambers 2 and 3, which communicate with each other through the transport chamber 4. This structure permits the substrate W to be transferred from the chamber 2 to the chamber 3 and vice versa without being exposed to the atmosphere. The chambers 2 and 3 are so designed as to perform reactive heat CVD for film forming, and the chamber 2 is also capable of film forming by plasma CVD.

These chambers 2 and 3 are connected to evacuating means, such as tube molecular pump (TMP), and automatic pressure control (APC) means (both not shown), so that they maintain a desired internal pressure.

In addition, the chambers 2 and 3 each have the lower electrode 5 and the upper electrode 6, which are opposite to each other. The lower electrode 5 functions also as substrate supporting means. The upper electrode 6 functions also as gas diffusing means. The lower and upper electrodes 5 and 6 in the chamber 2 are connected to the radio frequency (RF) power source 7, and the lower electrode 5 (which functions as substrate supporting means) is provided with heating means 8. The heating means 8 may be an electric heater, which keeps the substrate W placed on the lower electrode 5 at 200 to 600° C.

The upper electrode 6 (which functions as gas diffusing means) is connected to gas supply means 9 which supplies more than one species of gas to the chamber 2. The gas supply means 9 is connected to as many lines (not shown) as gases necessary for film forming, so that the chambers 2 and 3 are supplied with the film forming gas G composed of raw material gases and diluent gases in a desired ration. The film forming gas G includes silane (SiH₄), ammonia (NH₃), oxygen dinitride (N₂O), disilane (Si₂H₆), fluorine (F₂), germaniums tetrafluoride (GeF₄), phosphine (PH₃), diborane (B₂H₆), arsine (AsH₃), nitrogen (N₂), oxygen (O₂), helium (He), argon (Ar), and hydrogen (H₂). Each of the gas supply means 9 is provided with a mass flow controller (MFG) 9a, which controls separately the gas supply to the chambers 2 and 3.

The ratio frequency power source (RF) 7, the power source of the heating means 8, and the mass flow controller 9a are under control by a sequence controller 10 connected thereto.

The manufacturing apparatus 1 constructed as mentioned above works in the following way to form an insulating film of silicon nitride or silicon oxide or the like. First, the gas supply means 9 introduces the film forming as G including SiH₄, NH₃, N₂O, O₂, and so forth into the chamber 2. Then, the radio frequency (RF) power source 7 applies high frequencies across the lower electrode 5 and the upper electrode 6. In this way an insulating film is formed by plasma CVD on the substrate W which is placed on the lower electrode 5.

Further, the manufacturing apparatus 1 works as follows to form a semiconductor thin film such as silicon thin film. First, the gas supply means 9 introduces the film forming gas G including Si₂H₆, F₂, Ar, and so forth into the chambers 2 and 3. Then, the lower electrode 5 is heated to about 450° C., without high frequencies being applied across the lower electrode 5 and the upper electrode 6. Under this condition, the raw material gases react with one another to excite and decompose themselves thereby depositing a polycrystalline silicon film through reactive heat CVD on the substrate W which is placed on and heated by the lower electrode 5. In addition, to form an N-type doped silicon thin film, the gas supply means 9 introduces the film forming gas G including Si₂H₆, F₂, Ar, PH₃, and so forth into the chambers 2 and 3. Likewise, to form a P-type doped silicon thin film, the gas supply means 9 introduces the film forming gas G including Si₂H₆, F₂, Ar, B₂H₆, and so forth into the chambers 2 and 3. Under this condition, a polycrystalline silicon film containing specific dopants is formed by reactive heat CVD.

The reactive heat CVD process that employs Si₂H₆ and F₂ involves the oxidation reduction reaction, in which Si₂H₆ is oxidized into Si by F₂. This reaction system gives rise to a hydrogen-free polycrystalline film having a crystal grain size ranging from 10 to 100 nm. P atoms and B atoms as dopants are caught into silicon lattices during film forming, and hence they are self-activated. Thus, a low-resistance N-type of P-type polycrystalline silicon film is obtained at the time of film forming without the necessity for activation annealing.

The above-mentioned film forming process is accomplished continuously in the chambers 2 and 3 as the species of gas in the film forming gas G which is supplied from the gas supply means 9 are switched. The procedure for a series of steps is controlled by the sequence controller 10.

A description is given below of the method for producing a thin film transistor by means of the above-mentioned apparatus 1.

### First Embodiment

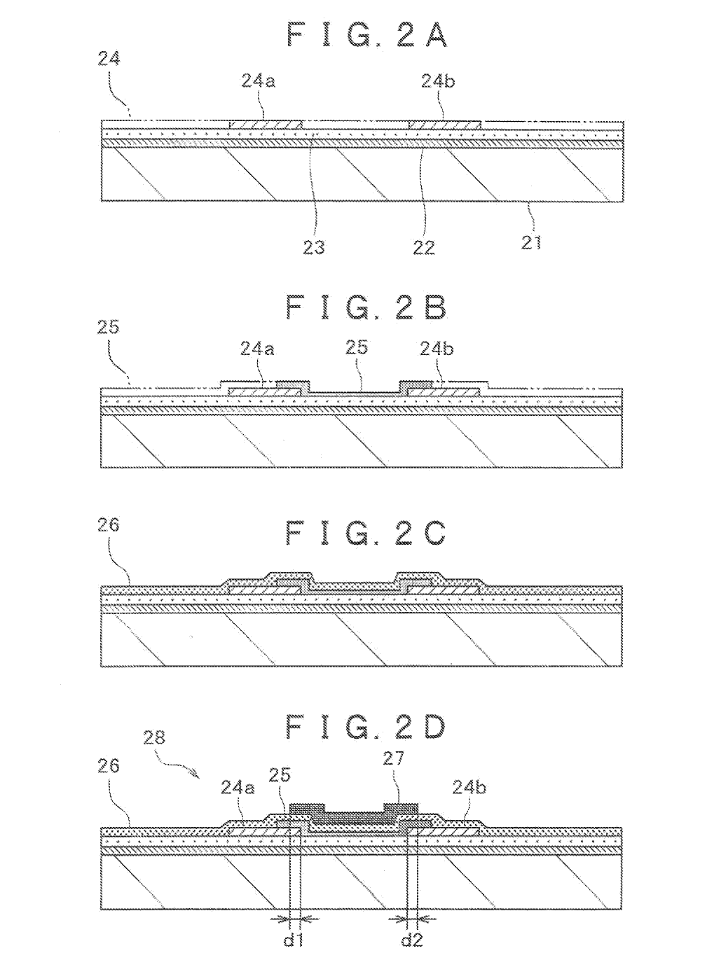

FIGS. 2A to 4B are sectional views which illustrate the method for producing thin film transistors in the first embodiment. The following is concerned with the method for producing a stacked TFT of top gate type as a thin film semiconductor device. The following is also concerned with the method for producing a display device with said stacked TFT's.

The first step is to prepare an insulating substrate 21 as shown in FIG. 2A. The substrate 21 may be AN635 or AN100 (from Asahi Glass) or Codel 1737 or Eagle 2000 (from Corning) or the like.

On the substrate 21 are sequentially formed a silicon nitride (SiNₓ) film 22 as a buffer layer and a silicon oxide film (SiOₓ) 23, which have a thickness ranging from about 50 to 400 nm.

Then, on the silicon oxide film 23 is formed by the reactive heat CVD process a source-drain layer 24 from polycrystalline silicon or polycrystalline silicon-germanium containing an n-type (or p-type) impurity. The source-drain layer 24 may be a single-layer film or a laminate layer composed of a doped polycrystalline silicon film and a doped polycrystalline silicon-germanium film. It should be 10 to 200 nm thick, preferably 100 nm thick.

The procedure for reactive heat CVD process to form the source-drain layer 24 from n-type polycrystalline silicon starts with heating the substrate at 450 to 600° C. The chamber is supplied with a film forming gas, a dopant gas, and a diluent gas. The film forming gas included disilane (Si₂H₆) and fluorine (F₂). The dopant gas includes phosphine (PH₃). The diluent gas is an inert gas, such as helium (He), nitrogen (N₂), argon (Ar), and krypton (Kr), or hydrogen (H₂). The flow rates of these gases are set up as follows.
disilane (Si₂H₆): 20 sccm
fluorine (F₂): 0.8 sccm
phosphin (PH₃): 1 sccm
helium (He): 1000 to 4000 sccm
   The gas pressure is kept at about 600 Pa.

Under the above-mentioned condition, Si₂H₆ and F₂ react with each other, thereby depositing n-type polycrystalline silicon at a rate of about 0.2 nm/s. The deposition of thin film is accompanied by crystallization, so that the activation of dopant takes place at the same time.

In the case where the source-drain layer 24 of p-type polycrystalline silicon is to be formed by the reactive heat CVD process, phosphine (PH₃) as a dopant gas should be replaced by diborane (B₂H₆).

In the case where the source-drain layer 24 of n-type or p-type polycrystalline silicon-germanium is to be formed by the reactive heat CVD process, fluorine should be replaced by germanium tetrafluoride (GeF₄). The resulting n-type or p-type polycrystalline silicon-germanium thin film varies in Si—Ge composition depending on the ratio of the flow rates of disilane (Si₂H₆) and germanium tetrafluoride (GeF₄).

The doped polycrystalline source-drain layer 24 formed as mentioned above subsequently undergoes patterning to form a source region 24a and a drain region 24b.

Then, an active layer 25 of impurity-free polycrystalline silicon or polycrystalline silicon-germanium is formed by the reactive heat CVD process in such a way that it covers the source region 524a and the drain region 24b, as shown in FIG. 2B. The active layer 25 should be about 20 to 100 nm thick, preferably 40 nm thick. The active layer 25 should be formed under the same film forming condition as explained above with reference to FIG. 2A, except that the dopant as is excluded. In addition, for prevention of cross-contamination with dopant, the active layer 25 should be formed in the chamber which is different from the one in which the above-mentioned impurity-containing polycrystalline source-drain layer 24 has been formed.

The active layer 25 undergoes patterning so that its edges overlap respectively with one edge of the source region 24a and one edge of the drain region 24b.

The substrate 1 is transferred to the other chamber for plasma CVD. A gate insulating film 26 of silicon oxide (SiOₓ) is formed, as shown in FIG. 2C. The gate insulating film 26 should be 10 to 200 nm thick, preferably 100 nm thick.

A gate electrode 27 is formed above the patterned active layer 25, with the gate insulating film 26 interposed between them, as shown in FIG. 2D. This object is achieved by patterning a conductive film of about 50 to 250 nm thick formed from tantalum (Ta), molybdenum (MO), tungsten (W), chromium (Cr), copper (Cu), or an alloy thereof.

This patterning is accomplished in such a way that both edges of the gate electrode 27 overlap respectively with one edge of the source region 24a and one edge of the drain region 24b, with the gate insulating film 26 and the patterned active layer 25 interposed between them.

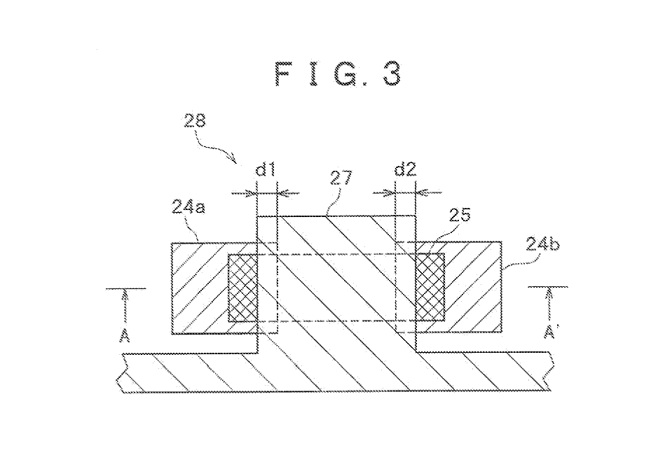

The overlapping sections are indicated by d1 and d2 in a plan view of FIG. 3. The overlapping sections d1 and d2 overlap each other planarly. The size (width and area) of the overlapping sections d1 and d2 should be as small as possible to reduce the parasitic capacity. However, it depends on the accuracy of the photolithography process. Consequently, it should be established within a range of about 0.5 to 1.0 μm according to the process employed. The overlapping sections d1 and d2 may differ in size from each other, it is desirable to reduce the parasitic capacity individually between the gate electrode 27 and the source region 24a and between the gate electrode 27 and the drain region 24b. In addition, either of the overlapping sections d1 and d2 may be omitted.

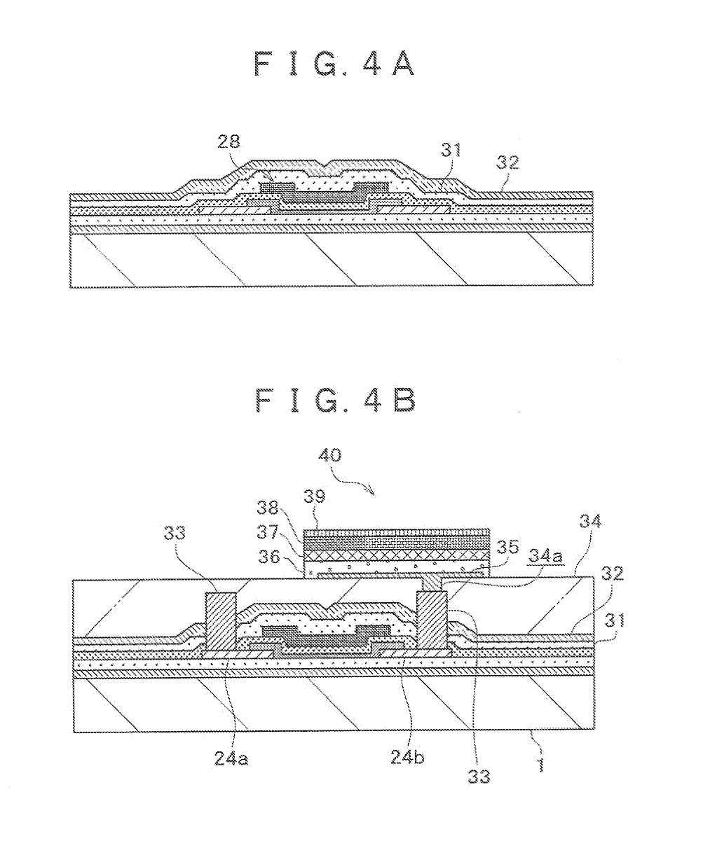

In the foregoing steps is formed a stacked TFT 28 of top gate type. Next, the TFT 28 is covered by a silicon oxide film 31 and a hydrogen-containing silicon nitride film 32, which are formed sequentially by the plasma CVD process, as shown in FIG. 4A. These layers function as an interlayer insulating film, which is 200 to 400 nm thick. This step is followed by annealing for hydrogenation in a nitrogen gas (N₂) atmosphere at 350 to 400° C. for about 1 hour.

Then, connecting holes are made in the silicon nitride film 32 and the silicon oxide film 31. Wiring electrodes 33 connecting respectively with the source region 24a and the drain region 24b are formed by sputtering with aluminum-silicon or the like and ensuring patterning, as shown in FIG. 4B.

The entire surface is coated with a planarized insulating film 34 of about 1 μm thick of acrylic organic resin or organic SOG. A connecting hole 34a reaching the wiring electrode 33 is made in the planarized insulating film 34. A film of Al, Cr, or Mo, or the like which fills the connecting hole 34a, is formed by sputtering. This film is patterned so as to form a pixel electrode 35.

The intermediate product undergoes annealing in a nitrogen atmosphere at about 220° C. for 30 minutes. On the pixel electrode 35 are sequentially formed a hole transport layer 36, an emitting layer 37, and an electron transport layer 38. On the top is formed a common electrode 39 which is a transparent conductive cathode. In this way, there is obtained an organic EL element 40 which is composed of an anode, or the pixel electrode 35, and a cathode, or the common electrode 39, and an organic layer held between them. The organic layer is composed of the hole transport layer 36, the emitting layer 37, and the electron transport layer 38.

Finally, a buffer layer that covers the organic EL element 40 is formed on the substrate 1. A glass plate is bonded to the substrate 1, with the organic EL element 40 interposed between them. (These steps are not shown.) Thus, a display device of top emission type is obtained. In other words, this display device has a top emission structure in which the device permits the organic EL element 40 to emit light through the transparent electrode 39 or the glass plate opposite to the substrate 1.

Incidentally, the display device is not restricted to that of top emission type but it may be of bottom emission type, in which the pixel electrode 35 is made of a transparent conductive material so that the organic EL element 40 emits light through the substrate 1. It is also possible to cause the pixel electrode 35 and common electrode 39 to function respectively as the cathode and anode. This is achieved by changing the arrangement of the hole transport layer 36, the emitting layer 37, and the electron transport layer 38.

The above-mentioned manufacturing method is characterized in that the source-drain layer 24 and the active layer 25 are formed by the reactive heat CVD process, as shown in FIGS. 2A and 2B, to form the TFT 28. This method offers the advantage of forming crystalline semiconductor thin films without additional steps for crystallization. Hence, it gives stacked thin film transistors having such semiconductor thin films laminated on top of the other. In other words, the source-drain layer 24 and the active layer 25 are composed of crystalline semiconductor thin films which do not need additional steps for crystallization. Therefore, the resulting TFT 28 works at a higher speed than the conventional TFT with amorphous semiconductor thin films.

Moreover, the omission of steps for crystallization removes variations due to crystallization, which contributes to uniform characteristic properties. Moreover, forming a previously doped crystalline semiconductor thin film as the source-drain layer 24 eliminates the step of introducing an impurity after film formation.

As explained above with reference to FIGS. 2D and 3, the gate electrode 27 is formed in such a way that its both edges overlap the edges of the source region 24a and the drain region 24b. This arrangement permits the active layer 25 to be held between the gate electrode 27 and the source region 24a and between the gate electrode 27 and the drain region 24b. The effect of this state is that the active layer 25 under the gate electrode 27 forms an inversion layer under the influence of the electric field generated by the voltage applied to the gate electrode 27 when the TFT 28 is ON. In this state, the edges of the source region 24a and the drain region 24b decrease in resistance, with the result that the ON current, or the driving current, of the TFT 28 increases. Incidentally, when the TFT 28 is OFF, that part of the active layer 25 which is held between the gate electrode 27 and the source region 24a and between the gate electrode 27 and the drain region 24b becomes depleted and increases in resistance. This reduces the OFF current.

The above-mentioned manufacturing method according to the present invention produces the following effects.
The method yields the stacked TFT 28 which is suitable to drive organic EL elements with a less number of manufacturing steps. Being formed from polycrystalline semiconductor films, the stacked TFT 28 works at a higher speed and realizes an increased driving current.
The method yields the stacked TFT 28 which is free of variations due to crystallization.
The method does not need the steps for crystallization and doping. This makes it possible to form uniform stacked TFT's 28 on a large substrate. Such TFT's help to realize a large-sized display device.

The advantage of the large-size display device as mentioned above is that selector switches are concentrated in peripheral circuits and hence connecting terminals for external circuits are greatly reduced. This helps realize a large-size display device characterized by high reliability, low cast, and low power consumption. An example of the large-sized display device is a large electroluminescence display with a diagonal line in excess of 40 inches. Although the foregoing description has been made with reference to a display device based on organic EL elements, the present invention will be applicable to any other display devices based on inorganic EL elements, liquid crystal display elements,

### Second Embodiment

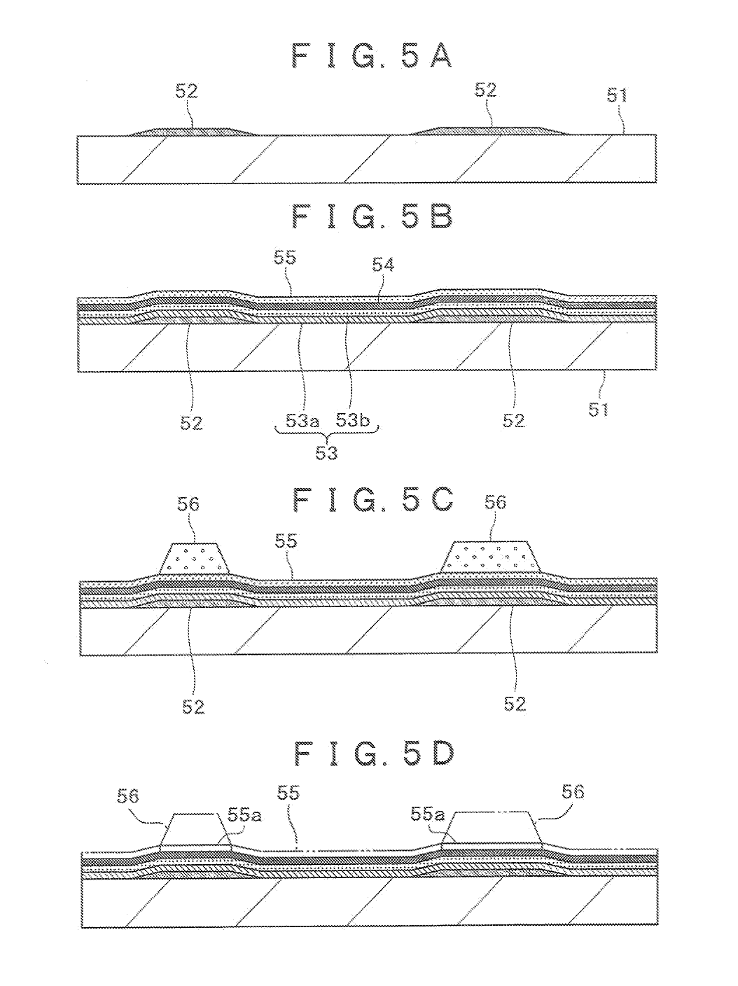

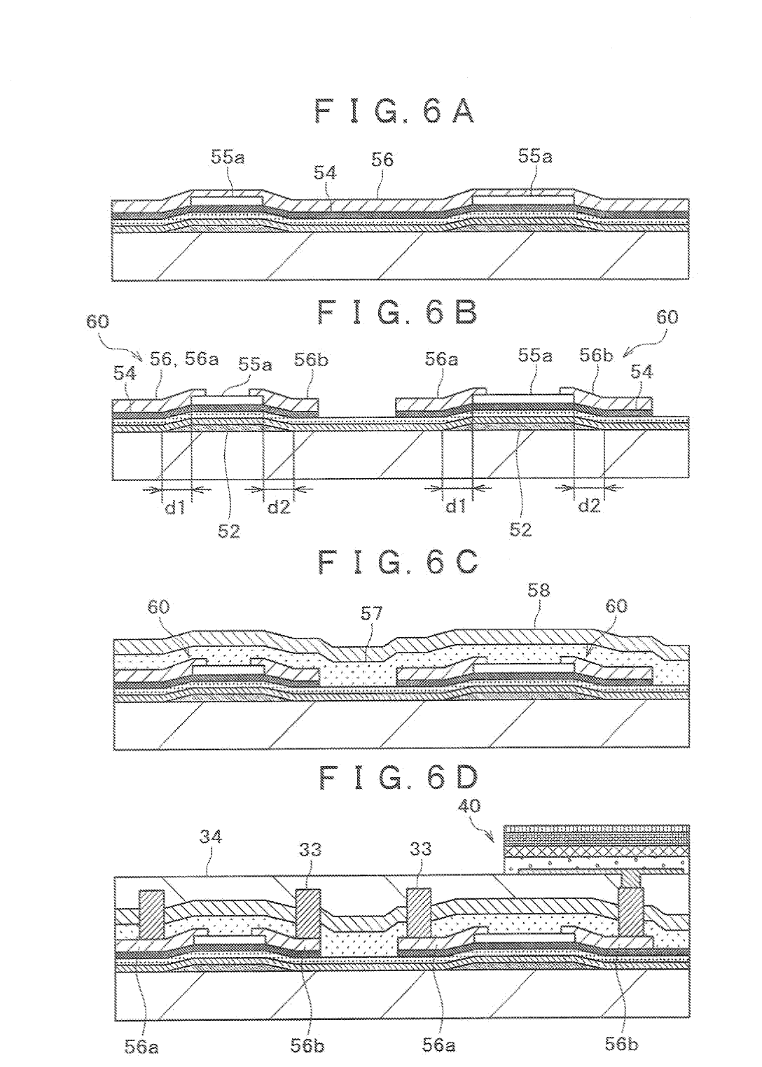

Sectional views of FIGS. 5 and 6 illustrate the method for producing thin film transistors in the second embodiment. The following is concerned with the method for producing a stacked TFT of bottom gate type as a thin film semiconductor device. The following is also concerned with the method for producing a display device with said stacked TFT's.

First, as shown in FIG. 5A, an insulating substrate 51 is coated with a conductive film of 50 to 250 nm thick of tantalum (Ta), molybdenum (Mo), tungsten (W), chromium (Cr), copper (Cu), or an alloy thereof, in the same way as in the first embodiment. Then, this conductive film is made into gate electrodes 52 by patterning.

Subsequently, as shown in FIG. 5B, a silicon nitride film 53a of 30 to 50 nm thick and a silicon oxide film 53b of 50 to 200 nm thick are sequentially formed by plasma CVD, atmospheric CVD, or reduced pressure CVD. The resulting laminate film is made into a gate insulating film 53.

Then, an active layer 54 of impurity-free polycrystalline silicon or polycrystalline silicon-germanium is formed by the reactive heat CVD process. The active layer 54 should be about 20 to 100 nm thick. The active layer 54 should be formed in the same way as in forming the active layer 25 for the first embodiment explained above with reference to FIG. 2B. Incidentally, the film forming gas may be incorporated with a trace amount of dopant gas so as to adjust the threshold voltage of the stacked TFT. The dopant may be selected according to the conductivity type of the stacked TFT to be formed. Then, a silicon oxide thin film 55 of about 100 to 200 nm thick is formed again by plasma CVD on the active layer 54.

A resist pattern 56 is formed on the silicon oxide film 55 by exposure from the back using the gate electrode 52 as a mask, as shown in FIG. 5C.

The silicon oxide thin film 55 undergoes etching through the resist pattern 56 as a mask, as shown in FIG. 5D, so that an etch stopper 55a of silicon oxide is formed. After that, the resist pattern 56 is removed.

Then, as shown in FIG. 6A, a source-drain layer 56 of polycrystalline silicon or polycrystalline silicon-germanium containing an n-type (or p-type) impurity is formed on the active layer 54 of impurity-free polycrystalline semiconductor in such a way that it covers the etch stopper 55a. The source-drain layer 56 may be formed in the same way as in forming the source-drain layer 24 in the first embodiment which has been explained above with reference to FIG. 2A.

After the foregoing steps, patterning and etching are performed on the source-drain layer 56 and the active layer 54 to form an island above the gate electrode 52. Then, the doped polycrystalline source-drain layer 56 is separated into two sections—the source region 56a and the drain region 56b—above the gate electrode 52. The result is shown in FIG. 6B.

In the step just mentioned above, the source-drain layer 56 should be separated above the etch stopper 55a such that both edges of the source region 56a and the drain region 56b overlap the gate electrode 52, with the active layer 54 interposed between them, as shown in a plan view of FIG. 7. The overlapping sections are indicated by d1 and d2 in FIG. 7. The overlapping sections d1 and d2 should not contain the parts which hold the etch stopper 55a between them. Incidentally, the overlapping sections d1 and d2 should be set up in the same way as in the first embodiment.

Incidentally, in a sectional view of FIG. 6B showing two stacked TFT 60, the source region 56a and the drain region 56b may be of multi-gate structure continuously formed in a belt-like pattern or multi-gate structure with three or more of the gate electrode 52 (which are not shown). In this case, the overlapping section may be formed between only one of the gate electrodes 52 for multi-gate structure and the source region 56a and between only one of the gate electrodes 52 for multi-gate structure and the drain region 56b.

After the foregoing steps, the stacked TFT 60 of bottom gate type is obtained.

Next, the stacked TFT 60 is covered by a silicon oxide film 57 of 100 to 400 nm thick and a hydrogen-containing silicon nitride film 58 of 100 to 400 nm thick, which are formed sequentially by the plasma CVD process, as shown in FIG. 6C. This step is followed by annealing for hydrogenation in a nitrogen gas (N₂) atmosphere at 350 to 400° C. for 1 hour.

Then, the step shown in FIG. 6D is carried out to form the organic EL element 40 in the same way as in the first embodiment which has been explained above with reference to FIG. 4B. The organic EL element 40 is formed on the planarized insulating film 34 and is connected to the source region 56a and the drain region 56b through the wiring electrode 33.

The TFT 60 according to the second embodiment, which has been produced by the above-mentioned steps, has the same advantage as that according to the first embodiment. It has the source-drain layer 56 and the active layer 54 formed by the reactive heat CVD process, as explained above with reference to FIGS. 5B and 6A. It also has the source region 56a and the drain region 56b arranged such that their edges overlap both edges of the gate electrode 52, as explained above with reference to FIGS. 6B and 7. The effect of this structure is that the active layer 54 is held between the gate electrode 52 and the source region 56a and between the gate electrode 52 and the drain region 56b, as in the case of the first embodiment.

The above-mentioned manufacturing method according to the present invention produces the following effects.
The method yields the stacked TFT 60 which is suitable to drive organic EL elements with a less number of manufacturing steps. Being formed from polycrystalline semiconductor films, the stacked TFT 60 works at a higher speed and realizes an increased driving current.
The method yields the stacked TFT 60 which is free of variations due to crystallization.
The method does not need the steps for crystallization and doping. This makes it possible to form uniform stacked TFT's 60 on a large substrate. Such TFT's help to realize a large-sized display device.

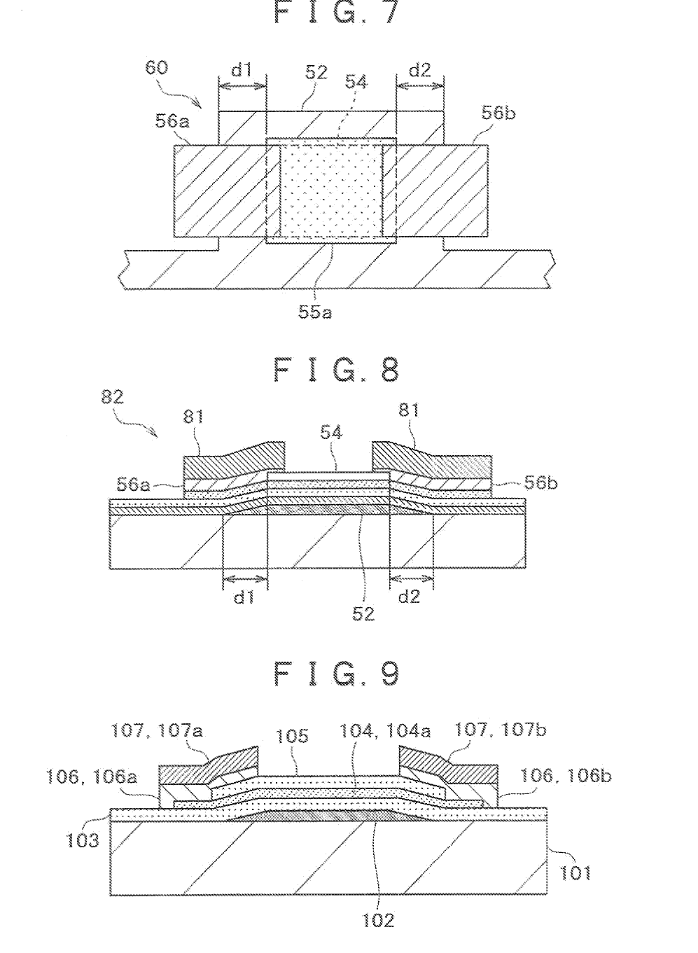

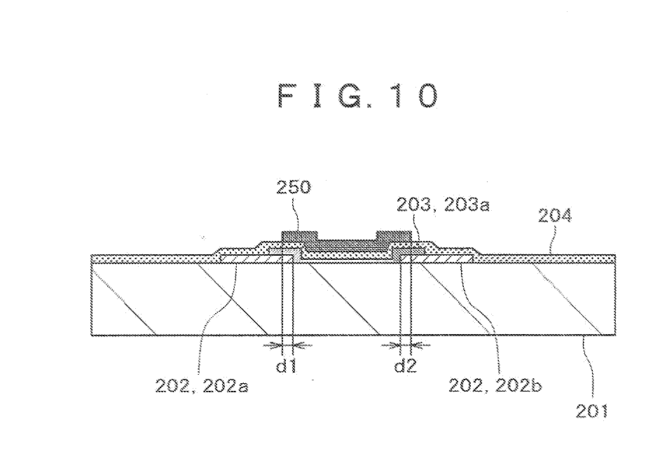

The manufacturing method of the present invention may be applied to the stacked TFT of bottom gate type which is constructed such that the wiring electrodes 81 are formed directly above the source region 56a and the drain region 56b, as shown in FIG. 8. This structure permits the number of masks to be reduced, because the source-drain layer 56 which has been explained with reference to FIG. 6A is formed and then the layer for the wiring electrode is formed on the source-drain layer 56 and finally the source-drain layer 56 and the layer for the wiring electrode are patterned at the same time. However, before the layer for the wiring electrode is formed on the source-drain layer 56, it is possible to perform hydrogen plasma treatment, oxygen plasma treatment, or steam annealing to lower the defect level of the polycrystalline silicon constituting the source-drain layer 56.

The stacked TFT 82 produced in this manner produces the same effect as the stacked TFT according to the second embodiment, if the source-drain layer 56 and the active layer 54 are formed by the reactive heat CVD process and the source region 56a and the drain region 56b are arranged such that their edges overlap both edges of the gate electrode 52 in the same way as in the second embodiment. Moreover, it produces an additional effect of reducing the number of masks as compared with the second embodiment.

While preferred embodiments of the present invention have been described using specific terms, such description is for illustrative purposes only, and it is to be understood that changes and variations may be made without departing from the spirit or scope of the following claims.

1. (canceled)

2. A method for producing a thin film transistor which comprising the steps of:
forming a gate electrode on a substrate and then covering the gate electrode with a gate insulating film;
forming on said gate insulating film an active layer of polycrystalline semiconductor thin film by heating the substrate and contacting the substrate with a film forming gas and a dopant gas;
forming a source-drain layer of polycrystalline semiconductor thin film containing impurities by the active heat CVD process that employs the reaction energy of different two or more gases; and
forming a source region and a drain region by patterning said source-drain layer in such a way that both ends of said gate electrode overlap the edges of said source region and drain region in a specific manner with said gate insulating film and active layer interposed under said gate electrode.

3. (canceled)
